(19) United States
(12) Patent Application Publication
(10) Pub. No.: US 2011/0215344 A1
(43) Pub. Date: Sep. 8, 2011

(54) LOW POWER GRADED BASE SiGe HBT LIGHT MODULATOR

(76) Inventors: Henry D. Dardy, Upper Marlboro, MD (US); Jong Ru Guo, Fishkill, NY (US); John F. McDonald, Clifton Park, NY (US); S. Mary Ann Dardy, Columbia, SC (US)

(21) Appl. No.: 13/040,988

(22) Filed: Mar. 4, 2011

Related U.S. Application Data
(60) Provisional application No. 61/310,754, filed on Mar. 5, 2010.

(51) Int. Cl. H01L 31/153

(52) U.S. Cl. 257/83; 257/E31.102

(57) ABSTRACT

A graded base silicon-germanium (SiGe) heterojunction bipolar transistor (HBT)-based electro-optical (EO) modulator includes a graded base HBT and a light beam directed under the graded base HBT and passing through the free carrier plasma within for the purpose of inducing a phase modulation of the light beam.

### CROSS-REFERENCE TO RELATED APPLICATIONS

This Application claims the benefit of U.S. Provisional Application 61/310,754 filed on Mar. 5, 2010 and incorporated herein by reference.

### BACKGROUND OF THE INVENTION

Fast modulation of optical signals with low cost devices is of great interest to many fields ranging from on-chip or intra-chip interconnections to Si photonics for telecommunication. Among the different technologies proposed to develop modulators, silicon photonics is one of the most promising as it allows mass production at an attractive cost, and can allow monolithic integration with advanced electronics on a single die. Electro-optical effects in strained silicon or quantum-confined stark effect in SiGe/Ge quantum wells have been demonstrated recently, but at the moment fast modulators integrated in silicon are based on the plasma dispersion effect. A three terminal Bipolar Mode FET (BMFET) integrated in a low loss single mode SOI waveguide with a switching time of less than 3.5 ns and π-phase shift interaction length (L_{π}) of 1 mm has been described in the literature, and more recently there has been described a P-I-N silicon modulator, with bit rates of 10 Gb/s, and an L_{π} of 100 to 200 μm. Another device recently described is a PN junction based fastest modulator of 40 Gb/s with an L_{π} of 1 mm, using a carrier depletion structure combined with travelling wave electrodes. Another device described in the literature as a depletion mode PN junction based SOI modulator was reported with rise and fall times of 7 ps with an effective bandwidth of 60 GHz. A shorter EO modulator length has been demonstrated by incorporating resonant light-confining structures in the device. Group III-V-based travelling wave electro-absorption modulators (TWEAM) using a high quantum-confined stark effect have been reported to operate at 80-100 Gbits/s.

One pathway to modulate light is based on the traditional Mach Zender interferometer structure (MZI). However, the proposed approach to light modulation also impacts many photonic optical structures that involve phase shift of a light beam induced by the so called free carrier effect. A generic photonic structure that could utilize this effect is shown in FIG. 1. In this structure which can be used as a crossbar router, light enters on one or both of the left most ports with intensities I₂ (E₂), I₁(E₁), and using the subject patent device capable of slowing the light as a phase shifter, light can be routed to one leg or the other leg of two output ports with output intensities of I₄(E₄) and I₃(E₃), using couplers with coupling coefficients of k₁ and k₂. This structure can be used to turn the light on and off at one of the output ports, to route light from one input port to an output port, or if the coupling coefficients are designed right, mix them with additive gains. If the phase shift of an optical carrier signal is shifted by π, then light passing along the top leg and the bottom leg can effectively cancel each other if the coupling coefficients are balanced. FIG. 1 shows that application of the HBT as a general Drude Effect photonic component.

These structures need to bring two optical guides close together to induce directional coupling as shown in FIG. 1, where the coupling factor is the two “close encounters” of k₁ and k₃.

Following Okamoto, the Jones matrix representation of the fields at the outputs of the combiner mixer is given by

$$[ \begin{matrix}{E}_{3} \\ {E}_{4}\end{matrix} ] = {M}_{D 1} {M}_{AM} {M}_{D 2} [ \begin{matrix}{E}_{1} \\ {E}_{2}\end{matrix} ]$$

$${M}_{D 1} = [ \begin{matrix}cos ( κ d ) & j sin ( κ d ) \\ j sin ( κ d ) & cos ( κ d )\end{matrix} ]$$

$${M}_{AM} = [ \begin{matrix}exp ( j Δ φ / 2 ) & 0 \\ 0 & exp ( - jΔ φ / 2 )\end{matrix} ]$$

where d is the length of the directional coupling sections, and Δφ is the amount induced by the phase shifter. Defining

k=sin²(κd)

one can compute the intensities corresponding to the two output fields E3 and E4.

$${I}_{3} = \{ {( \sqrt{( 1 - {k}_{1} ) ( 1 - {k}_{2} )} - \sqrt{{k}_{1} {k}_{2}} )}^{2} + 4 {sin}^{2} ( Δ φ / 2 ) \sqrt{{k}_{1} {k}_{2} ( 1 - {k}_{1} ) ( 1 - {k}_{2} )} \} {I}_{1} + \{ ( \sqrt{{k}_{1} ( 1 - {k}_{2} )} - \sqrt{{( 1 - {k}_{1} ) {k}_{2} )}^{2}} + 4 {cos}^{2} ( Δ φ / 2 ) \sqrt{{k}_{1} {k}_{2} ( 1 - {k}_{1} ) ( 1 - {k}_{2} )} \} {I}_{2} \\ {I}_{4} = \{ {( \sqrt{{k}_{1} ( 1 - {k}_{2} )} - \sqrt{( 1 - {k}_{1} ) {k}_{2}} )}^{2} + 4 {cos}^{2} ( Δ φ / 2 ) \sqrt{{k}_{1} {k}_{2} ( 1 - {k}_{1} ) ( 1 - {k}_{2} )} \} {I}_{1} + \{ {( \sqrt{( 1 - {k}_{1} ) ( 1 - {k}_{2} )} - \sqrt{{k}_{1} {k}_{2}} )}^{2} + 4 {sin}^{2} ( Δ φ / 2 ) \sqrt{{k}_{1} {k}_{2} ( 1 - {k}_{1} ) ( 1 - {k}_{2} )} \} {I}_{2}$$

One then has a system component that can mix signals from two sources with mixing coefficients that can be adjusted through the k (coupling coefficients) and

Δφ=2πnΔL/λ,

Most work in the past for light modulatin has been dominated by advanced physics studies involving Multiple Quantum Well and other quantum effect structures, such as the Stark Effect in SiGe. However these structures are not in the panoply of existing Silicon devices manufactured today. It would be extremely difficult to incorporate such devices into existing manufacturing flows where photonics could be quickly adopted, and disseminated throughout the infrastructure. Instead a pre-quantum mechanical idea due to Paul Drude in the early 1900's has shown promise. It utilizes the tendency for carrier plasma in semiconductors to lower the propagation velocity of light as it passes through the plasma.

INTEL announced in the 2004 issue of NATURE that it had successfully modulated light in silicon using the Drude effect by reflecting light in the region of Silicon under the active carrier plasma under a FET capacitor structure. Early results demonstrated 2.4 Gb/s as a bit rate, and this has now been improved to 10 Gb/s. Part of the trick for attaining 10 Gb/s was developing a driver for the huge 2.5 mm W (channel “width”) of the phase shifting FET capacitor. Additionally there is a requirement for L (channel length) of one wavelength because the “channel length” of the structure has to be comparable to a wavelength of light. This limits the fT of this FET free carrier light modulator device. The light modulator involves a phase shift from passing light through the carrier plasma in the thin inversion region of along a very long FET capacitor (2.5 mm in one case) until a phase shift of π was obtained. The structure is shown in FIG. 2.

The Drude Effect creates a kind of programmable dielectric in the hole-electron plasma region with changes in effective optical index and attenuation per unit length given by:

$$Δ n = - \frac{{e}^{2} {λ}^{2}}{8 {π}^{2} {c}^{2} {ɛ}_{0} n} ( \frac{Δ {N}_{e}}{{m}_{e}} + \frac{Δ {N}_{h}}{{m}_{h}} )$$

$$Δ α = \frac{{e}^{2} {λ}^{2}}{4 {π}^{2} {c}^{3} {ɛ}_{0} n} ( \frac{Δ {N}_{e}}{{m}_{e}^{2} {μ}_{e}} + \frac{Δ {N}_{h}}{{m}_{h}^{2} {μ}_{h}} )$$

Soref has published empirical modifications of these equations where additional semiconductor effects exist at a wavelength of 1.55 microns.

Δn=Δnₑ+Δnₕ=−[8.8×10⁻²²ΔNₑ+8.5×10⁻¹⁸(ΔNₕ)^{0.8}]

Δα=Δαₑ+Δαₕ=8.5×10⁻¹⁹ΔNₑ+6.0×10⁻¹⁸ΔNₕ

where the subscript “e” and “h” denote the electron and hole contributions to the change in index seen by the light as it passes through the free carrier plasma. One can see a slight nonlinearity in the hole component. One can also see from the change in the index of refraction that light passing through the graded base SiGe HBT can be slowed down based upon voltages applied to the HBT, which alters the free carrier densities and that this slowing of light introduces a phase shift. Hence the graded base SiGe HBT is a kind of phase shift modulator.

Here Δn and Δα are the variation of the real part of the refractive index (n) and of the absorption coefficient (α) when the free carrier concentration deviates from the values of the intrinsic semiconductor; e is the electron charge, ε₀ is the dielectric constant in free space, n is the refractive index of intrinsic Si, μ is the free carrier mobility, m_{c},mₕ are the effective (i.e. normalized) masses, ΔN is the free carrier concentration variation, and λ is the wavelength. The subscripts e and h refer to electrons and holes, respectively. Since the effective masses are on the order of 0.1-1.0, and the electron and hole mobilities are 1450 and 505 in the cgs-volt system respectively, one can see that the attenuation change effect is in Si semiconductors. This is primarily due to the factor of the speed of light c³ in the denominator for Δα vs. c² for Δn. The Si based Drude Effect device is essentially a phase modulator whose change depends on plasma carrier density changes induced by device voltage changes. The imaginary part of the index, namely k, is for undoped silicon typically between 5 and 9 orders of magnitude down from the real part, n in the range of 1-1.4 um for IR (Palik). Hence, on a materials and device basis, loss is very low in the Si materials system. In these formulas it is important to keep in mind the relation between the attenuation coefficient α, the extinction coefficient k, and wavelength:

α=4π k̅/λ₀

As can be seen from these equations the phase shift one can induce depends on the general order of magnitude of carriers in the semiconductor which tends to be set by the maximum doping densities compatible with normal CMOS operation and this is typically around 10¹⁷ per cubic centimeter. The other factor is the volume over which the carriers are concentrated by the device, and particularly the volume over which the light photons actually interact with the carrier plasma. For the FET device this is restricted to an extremely thin region of inversion or accumulation near the thin oxide, typically one or two Debye lengths or about 200-400 Angstroms. MEDICI can be used to compute this carrier density. Using the meshing profile shown in FIG. 3 we can have these distributions computed. Since the thickness of the profile is much thinner than a wavelength of light in Si the light must be made to interact repeatedly with the plasma.

Since a primary focus is the hole concentration for the npn HBT the FET selected is the p-channel device in CMOS for comparison, as shown in FIG. 4.

In spite of very high doping in the source drain region the absolute maximum carrier density in deep channel inversion is only 2×10¹⁷, and has fallen already to half its peak at about 400 Ångstroms. The INTEL device was used for the phase shifting capability of the Drude Effect in a Mach Zender Interferometer structure as shown in FIG. 5. The Mach Zender interferometer structure is used to mix the shifted and un-shifted (or differentially shifted) light at the rejoining point where interference can take place leading to a kind of amplitude adjustment, i.e. at the point where the phase difference between the two legs of the interferometer becomes it and total cancellation of the beams (scattering out of the guide) occurs. Phase shift is induced in these light paths by virtue of passing the light through devices which contain free carrier plasma. Hence, diminished or zero light intensity is propagated past the mixing point. Mach Zender Interferometers are accordingly speed limited by the dissimilarity between the speed of light passing through the device vs. the speed at which RF propagates down the same device. For example, a change in the RF voltage is only affecting a light wavelet if it passes in tandem, down the guide with the associated light packet. Once these wavelets separate spatially the gain of the device as a phase modulator declines rapidly. This tends to happen if the two wavelets propagate over a long distance, e.g. long enough for them to separate by a wavelength. Hence the electrical structure has to be tuned to look like the photonic structure to the extent this is possible.

Although the INTEL breakthrough is significant and useful in these types of shifters, it has some disadvantages, primarily its large physical size, which exceeds several millimeters in length. Large physical size complicates creating large structures with many such phase shifters. This is because differences between RF and optical signal propagation velocity along the device can degrade the coherence between the applied RF signal and the corresponding light signal subjected to this RF signal. Large size also creates long optical paths which can accumulate loses.

The use of SiGe-on-Si technology for high speed optical modulation based on a free carrier plasma effect, where for a wavelength of 1.55 μm, an L, of 190 μm is obtained with an insertion loss of 4.7 dB, is described in R. D. Lareau, L. Friedman, and R. A. Soref, “Waveguided electro-optical intensity modulation in a Si/GexSi1-x/Si heterojunction bipolar transistor,” Electron. Lett. 26(20), 1653-1655 (1990) (“Soref”). It describes the structure shown in FIG. 6, a SiGe HBT with light passing through the base and possibly collector and emitter regions of the HBT, having a fixed and relatively high Si/Ge alloy ratio throughout the base (in that case 20% Ge alloy was considered). This limited the base doping to 10¹⁸ to have any decent beta. The light is mainly in the SiGe base region, ignoring hole concentrations in the emitter and collector. Because the doping density in the base was limited in this fixed Si/Ge alloy base the length of the device to achieve π phase shift for perfect extinction in a Mach Zender interferometer was about 390 um. As such its attenuation for a variety of reasons was about 10 dB at that length. Soref proposes that if only the injected carrier density could be one order of magnitude higher to 10¹⁹ then the length of the device could be shortened by order of 10×, lowering the injection loss, and predicts by simulation that in the SiGe base the device could be further shortened to at least 39 microns and still get π phase shift.

Younquian Jiang et al. in Applied Physics Letters describe the structure shown in FIG. 7 showing how the INTEL FET light modulator could be shortened to only 88 microns by incorporating a photonic crystal “slow wave” structure under the FET. This followed the suggestion of Notomi in a 2001 Phys. Rev. Lett. article that the backwards and forwards scattering which occurs in such slow wave structures permits a “reuse” of the plasma so that a given degree of phase shift could be attained in even shorter structures. What one does not desire, however, is to create a long ring down resonators structure. This limits the bandwidth attainable. The structure must remain an open ended but slow wave structure.

These prior art devices accordingly have disadvantages. The results for SiGe modulators that have been reported in the literature exhibited longer device lengths, and RC limited bandwidths. The FET has at least one obvious and inherent limitation. Its speed is inherently limited by its channel length. To reach an fT of 80 GHz the channel length must be less than 0.1 micron. The wavelength of infrared capable of propagating at low loss in Si is 0.8 micron. Since the direction of propagation is down the W direction of the FET, this puts a severe limitation on the channel length. It must be fairly wide compared with the wavelength of light. Hence, the FET is severely limited in the speed of modulation. The fastest modulator reported by INTEL using the FET is 40 Gb/s which suggests a bandwidth of 20 GHz. This in turn suggests a channel length of about 0.5 um at most if a single device is used. Multiple finger gate FET's are possible but one must account for source and drain contacts which separate the gate fingers.

It would therefore be desirable to provide a device without these limitations.

### BRIEF SUMMARY OF THE INVENTION

According to the invention, a graded base silicon-germanium (SiGe) heterojunction bipolar transistor (HBT)-based electro-optical (EO) modulator includes a graded base HBT and a light beam directed under the graded base HBT and passing through the free carrier plasma within for the purpose of inducing a phase modulation of the light beam.

The invention and the numerous applications incorporating the invention provide faster internet communication capabilities, and mitigation of what is termed the ultra narrow wire resistivity barrier which does not follow Moore's law scaling. The latter problem otherwise poses challenges for semiconductor manufacturers.

SiGe HBT is significantly smaller and more amenable to integrated circuit incorporation than a FET. The SiGe alloy can permit up to 2 orders of magnitude higher B doping in the base region (10¹⁹ cm⁻² up from 10¹⁷ cm⁻²), and especially with base pushout the volume would be much larger for the HBT than for the FET (400-md 1000 Å for the bipolar base and emitter thickness only—plus collector, vs. 2004 for the Debye length inversion channel thickness for the FET). However the high doping in the base would degrade beta, and in early SiGe HBT's this was a problem.

However with the advent of graded base SiGe HBT's the built in field resulting from the grading compensated the beta degradation from the high base doping, making the SiGe HBT an interesting device for manufacture for amplifiers, modulators, and logic devices. This found for the SiGe HBT a viable economic basis for manufacture, leading to eventual incorporation of this device into BiCMOS at companies such as IBM, Jazz, Infineon, ST Micro, and Phillips worldwide. While the majority of the industry is based on FET technology, the SiGe graded base HBT has a solid place in standard silicon technology. Here it can be interfaced monolithically with powerful microprocessors, analog circuits such as LNA's, VGA's and supporting interface circuits such as SERDES or Serializer Deserializers.

SiGe HBT SERDES work: Numerical analysis of the carrier density in a 2D model for the HBT was performed using the MEDICI device simulation and carrier modeling CAD program, with good results. The Drude Effect functions in the INTEL FET light modulator, and the graded base SiGe HBT provides improved performance. Secondarily since the graded base HBT light modulator uses a carrier plasma density to induce varying of the velocity of light and hence accumulated phase shift with a higher carrier density over a larger volume, that the light may be made to pass back and forth through this plasma to attain a reuse of the same carriers using a low Q resonant structure such as a slow wave structure, a photonic crystal. By reusing the same carriers, the injection current needed to place them into the volume of interaction may be significantly lowered, lowering the power needed for the modulator, and the device may be made more compact.

Another advantage of the HBT of the invention is its much higher doping density, therefore it can be much shorter than the FET, increasing the total amount of optical attenuation from Si absorption. The shorter the device the less current is required to place the plasma into that volume.

The SiGe graded base has an advantage over the original SiGe HBT investigated by Soref in the late 1980's because it permits higher doping densities without loss of the beta which would make the device useless for other millimeter wave applications. Also, silicon has been, are, and probably will be the materials system of choice for commercial electronics. Two and only two devices have a track record and have a justified existence for product production.

### BRIEF DESCRIPTION OF THE DRAWINGS

FIG. 1 is a schematic illustration of a conventional Mach Zender interferometer (MZI) structure;

FIG. 2 is a schematic illustration of a conventional Drude effect structure;

FIG. 3 is a meshing profile of the structure of FIG. 2;

FIG. 4 shows the hole concentration for a conventional npn HBT in CMOS;

FIG. 5 is a schematic illustration of a conventional Mach Zender Interferometer (MZI) structure;

FIG. 6 is a schematic illustration of a conventional a SiGe HBT structure;

FIG. 7 is a schematic illustration of a conventional FET light modulator;

FIG. 8 is a sectional view of a prior art graded base SiGe HBT;

FIG. 9 is a a sectional view showing additional details of the SiGe HBT of FIG. 8;

FIG. 10 is a cross section of the graded base SiGe HBT electro-optical (EO) modulator according to the invention;

FIG. 11 shows the MEDICI meshing for the EO modulator of FIG. 10 according to the invention;

FIG. 12 shows the hole profile for the EU modulator of FIG. 10 according to the invention;

FIG. 13 is a slow wave photonic crystal according to the invention;

FIG. 14 is a waveguide loaded with a periodic stud array;

FIG. 15 is a SiGe wafer bonded onto a SOI wafer according to the invention;

FIG. 16 is a layered structure according to the invention;

FIG. 17 shows precision wafer thinning by tomographic control using Sigma Tech Profiling and a MATECH linear sweep meniscus etchant system according to the invention;

FIG. 18 is SiGe graded base EO modulator positioned between a pair of dielectric resonators in a Fabrey Perot configuration according to the invention;

FIG. 19 is circuit schematic diagram of the SiGe graded base EO modulator according to the invention;

FIG. 20 is a high Q optical ring resonator according to the invention; and

FIG. 21 is an electrical circuit incorporating the graded base SiGe HBT according to the invention.

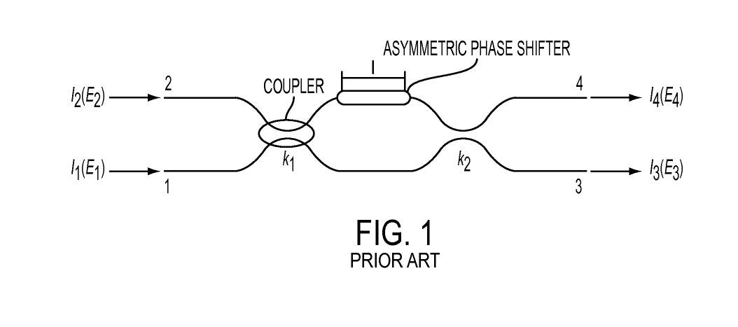

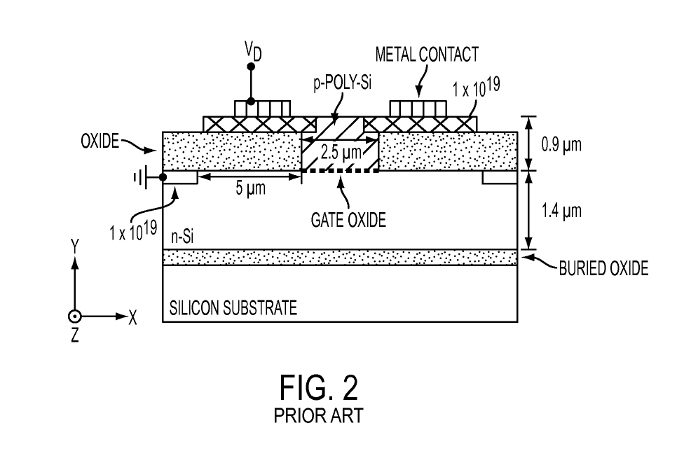

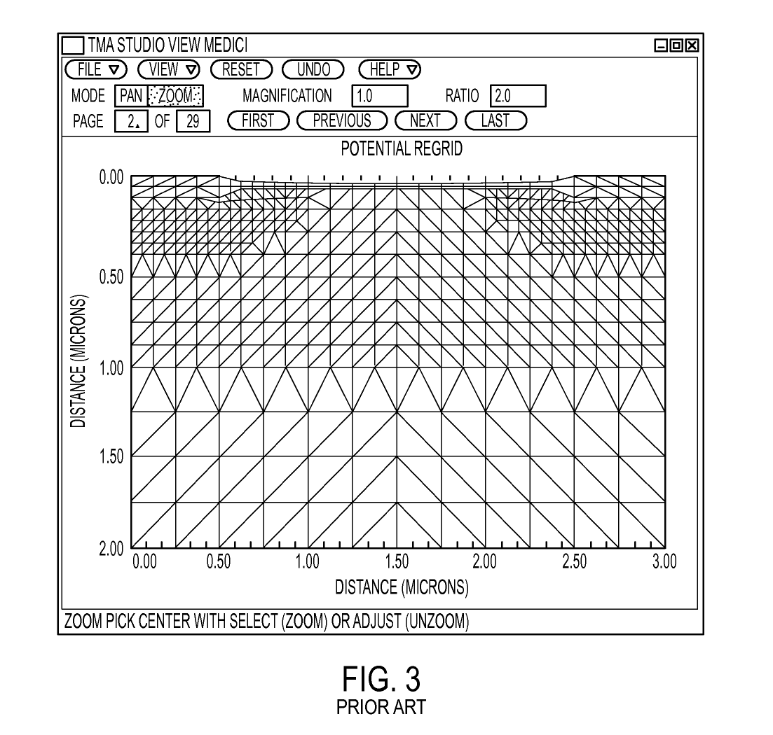

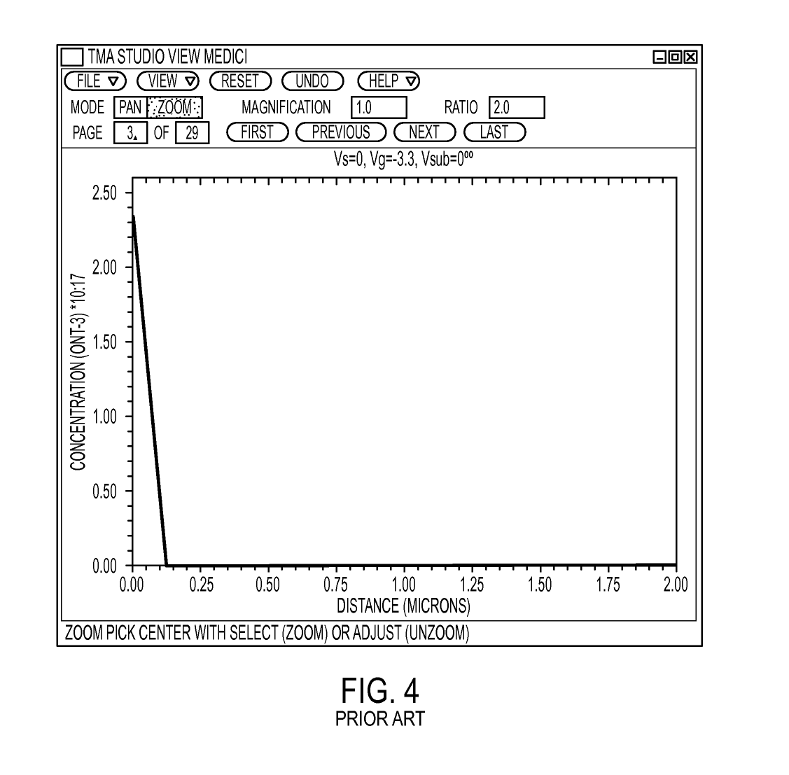

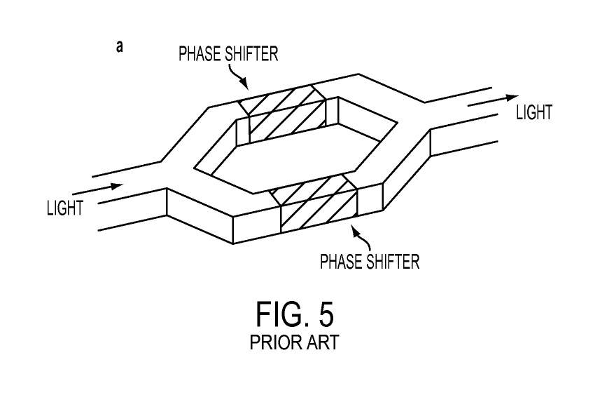

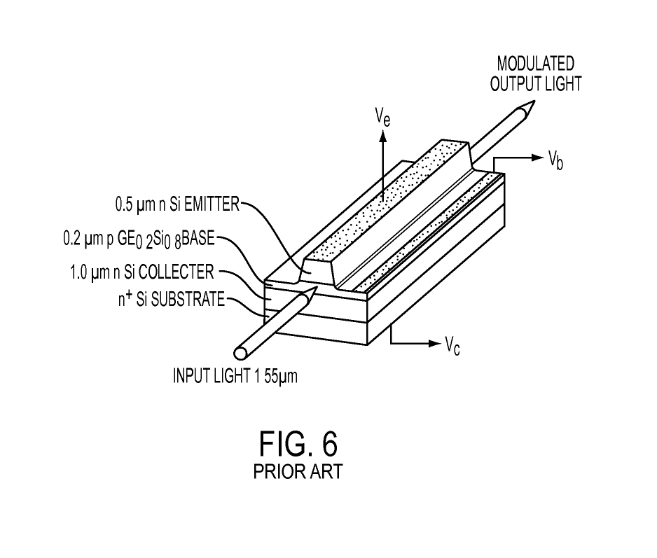

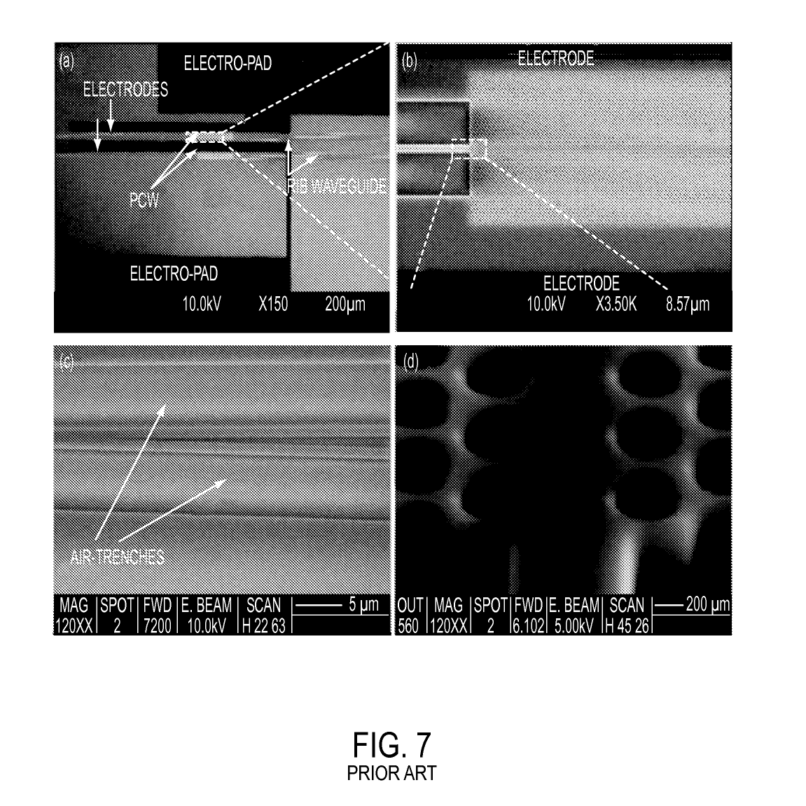

### DETAILED DESCRIPTION OF THE INVENTION

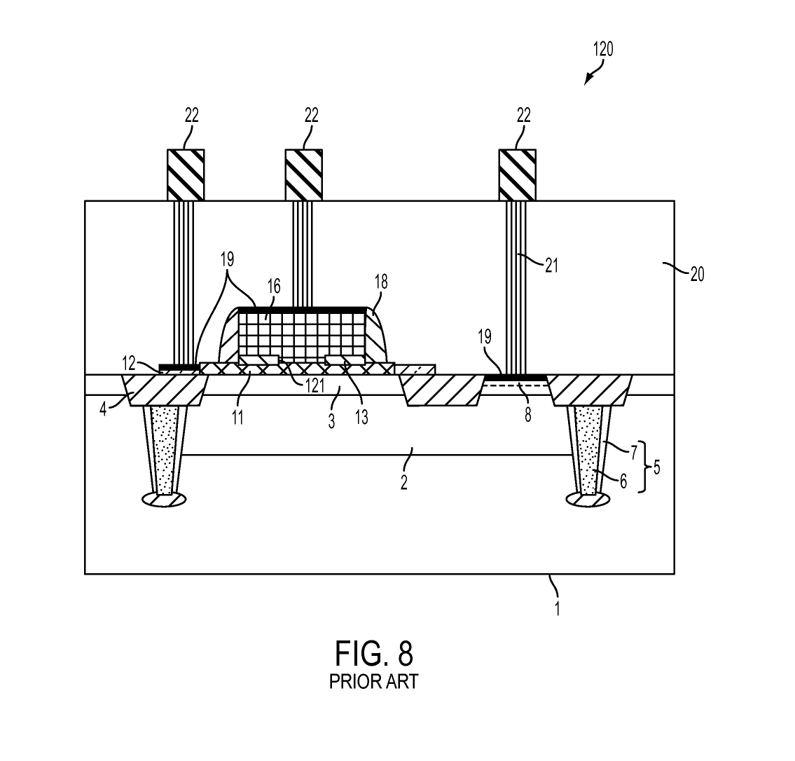

Referring now to FIGS. 8-10, the present invention is directed to a modified version of a graded base SiGe HBT 100 described in U.S. Pat. No. 7,719,031, issued May 18, 2010, (“Saitoh et al.”), and incorporated herein by reference, the modification/improvement being an additional element as discussed below that lends functionality as an electro-optical modulator. FIG. 8 is a sectional view showing an SiGe HBT in which a surface of P-type Si substrate 1 is doped with arsenic ions to form an N-type subcollector region 2 of about 1 micron depth. A Si monocrystal layer 3 0.5 micron thick is grown epitaxially on Si substrate 1 and subcollector region 2 with an N-type dopant covering both. A shallow trench 4 buried with a silicon oxide layer extends from a surface of the Si monocrystal layer 3 to the Si substrate 1 as an isolation region. A deep trench 5 comprising a non-dope polysilicon layer 6 and a silicon oxide layer 7 extends from trench 4. A HBT formation region is enclosed with the deep trench 5 and the subcollector region 2 is formed inside the Si substrate 1 enclosed with the deep trench 5. Phosphorus ions are implanted into the surface of layer 3 to form a N⁺-type collector extract layer 8. An extrinsic base region 11 is formed directly on the Si monocrystal layer 3 and an extrinsic base region of silicon oxide is formed on trench 4. A silicon oxide layer is 13 is formed on region 11 and provided with an open 121 partly exposing Si cap layer 112. An emitter electrode 16 is formed in contact with the surface of Si cap layer 112 via opening 121. Sidewalls 18 comprising silicon oxide insulate the emitter electrode 16. An interlayer dielectric 20 is deposited on substrate 1 with contact holes therein containing metal plugs 21 electrically connected to metal wiring 22 in interlayer dielectric 20 and to region 12, emitter electrode 16, and layer 8. A Co silicide layer 19 is formed on the surfaces of region 12, emitter electrode 16, and layer 8. The SiGe HBT accordingly comprises substrate 1, region 2, layer 3, trenches 4 and 5, layer 8, regions 11 and 12, layer 13, emitter electrode 16, sidewall 18, interlayer dielectric 20, metal plug 21, and metal wiring 22.

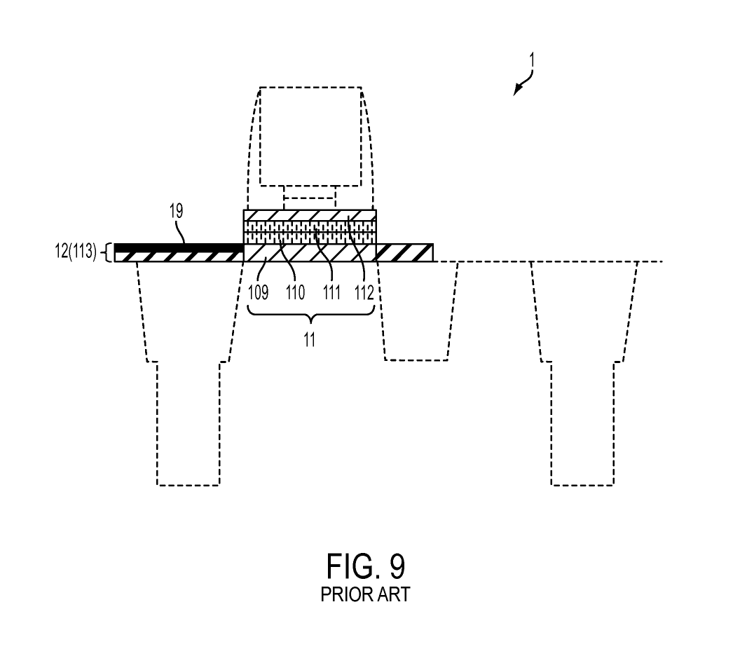

FIG. 9 is a sectional view showing the base layers 11 and 12 of the SiGe HBT. Region 11 comprises a monocrystal Si buffer layer 109, a monocrystal non-dope SiGe spacer layer 110, a monocrystal B-doped SiGe graded base layer 11, and a monocrystal Si cap layer 112. Region 12 comprises a polycrystal extrinsic base formation Si layer 113 and a Co silicide layer 19, formed on substrate 1.

The B-doped SiGe graded base layer 11 (composition-rate graded base layer) has a composition ratio of germanium to silicon that varies in its thickness direction, with the Ge content decreasing toward the top, thus forming a gradient of a bandwidth on the base layer to accelerate electrons.

Graded base SiGe HBT 100 operates as a Drude Effect phase shifter that is enhanced by also including a photonic crystal slow wave-guide designed to further shorten the device and reduce losses further. It operates in the range disclosed by Soref while providing phase shift devices as short as 10 microns.

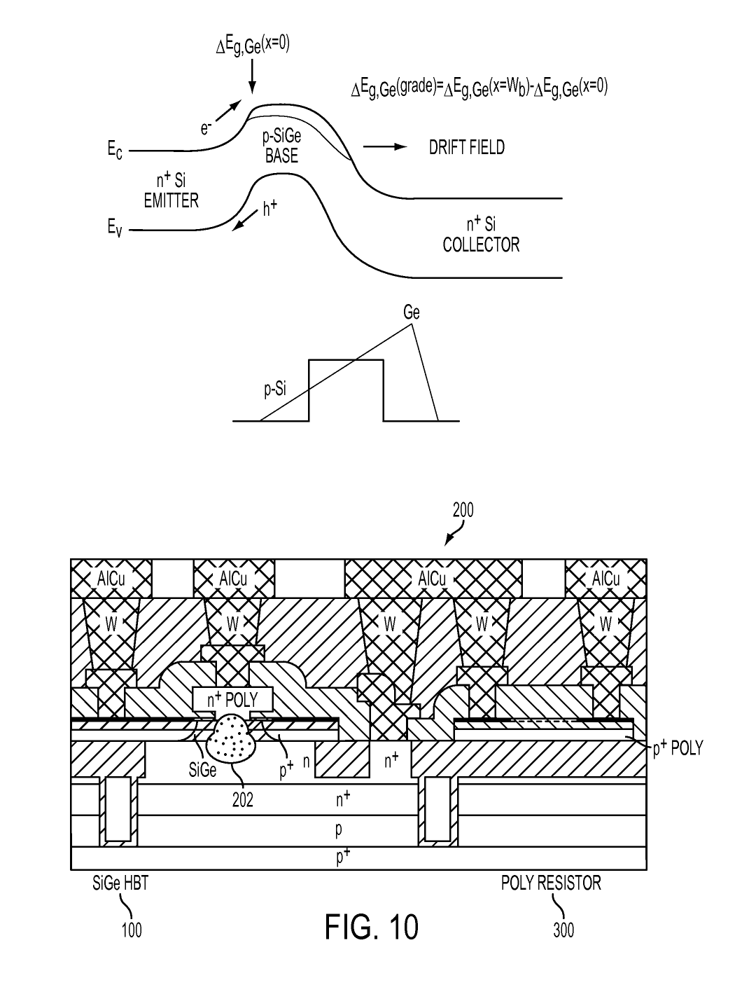

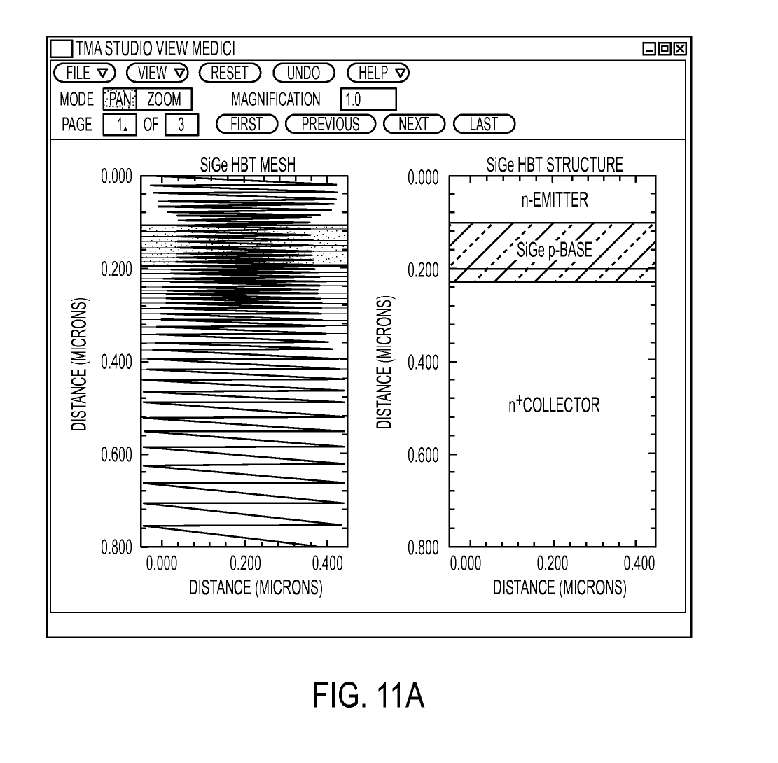

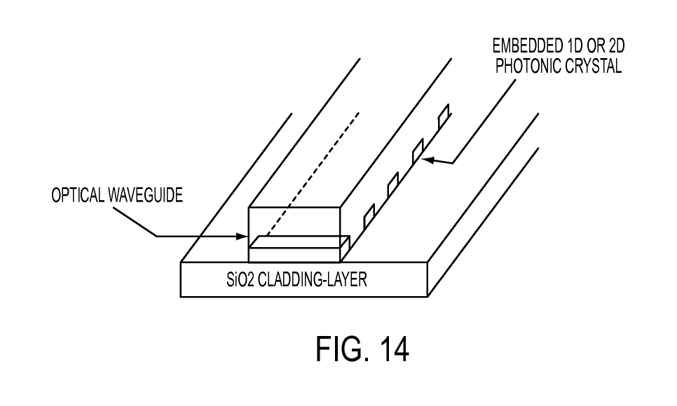

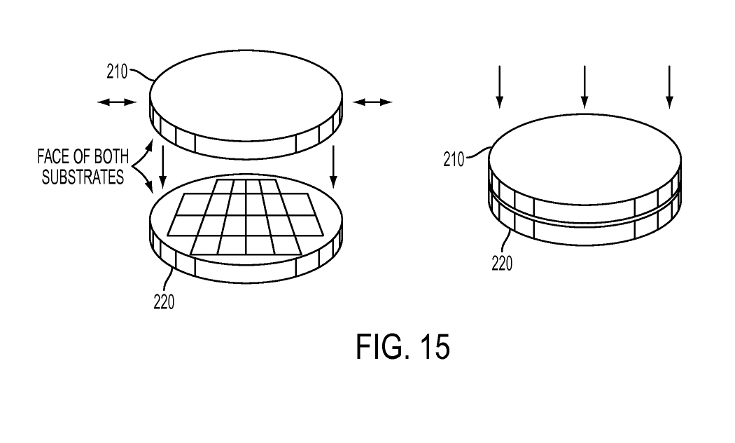

The cross section of the graded base SiGe HBT electro-optical (EO) modulator 200 with the light modulating functionality-adding light source 202 is shown in FIG. 10. The graded base HBT 100 component is shown to the left in this figure, whilst a resistor 300 is shown to the right. Observe the Oxide filled Deep Trench Isolation (DTI) structures on either side of the HBT. The vertical dimension of this drawing is distorted as the depth of the DTI is about 6 microns while the width of the DTI is only 1 micron. These DTI walls can form the sidewalls of a subsurface waveguide section. The SiGe HBT uses vertical band gap engineering by grading the base alloy of Si:Ge ratio by weight (mole fraction) from 2% to 7% across the base region. This is the region in the figure labeled SiGe. Because of this the device receives an exponential kick upwards in beta, which is partially traded in the device for much higher base doping to lower base resistance. In fact the doping is 10¹⁹ or two orders of magnitude higher than in the INTEL device, and one order of magnitude higher than wished for by Soref in 1990. Additionally the thickness of the base is much larger than the thickness of an inversion or accumulation layer in a FET. MEDICI simulation reveals the hole density profile across the centerline of the emitter, base, and collector. FIG. 14, shows the MEDICI meshing to produce the hole distributions shown in FIG. 15. Notice that we have only shown results for 10¹⁸ peak doping density (the results for 10¹⁹ are even better). Enhanced injection is due to the base alloy grading again.

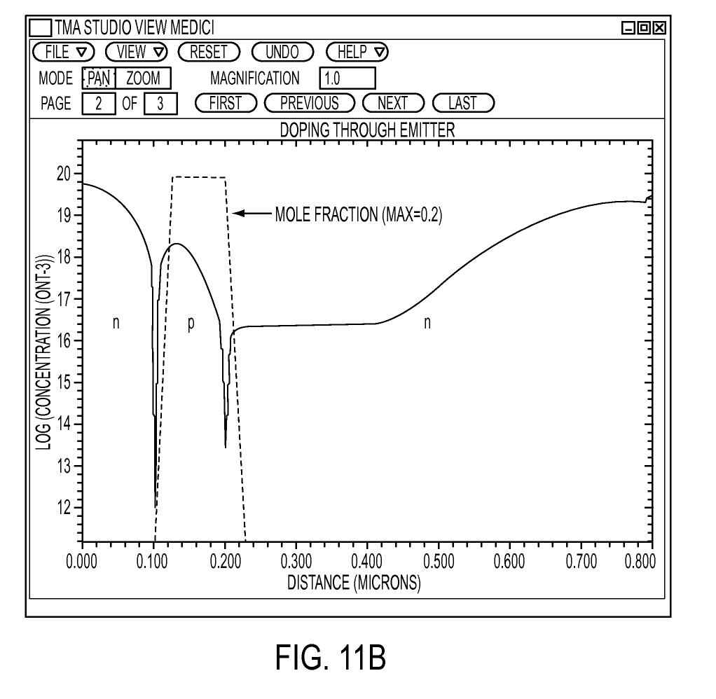

The MEDICI meshing for HBT showing SiGe base at 1000 Angstroms and doping profile used to obtain the injected current and carrier distributions under in and under the HBT is shown in FIG. 11. The MEDICI simulation of the SiGe HBT was for injected current carrier concentration only and we focus next on hole concentration in the collector region.

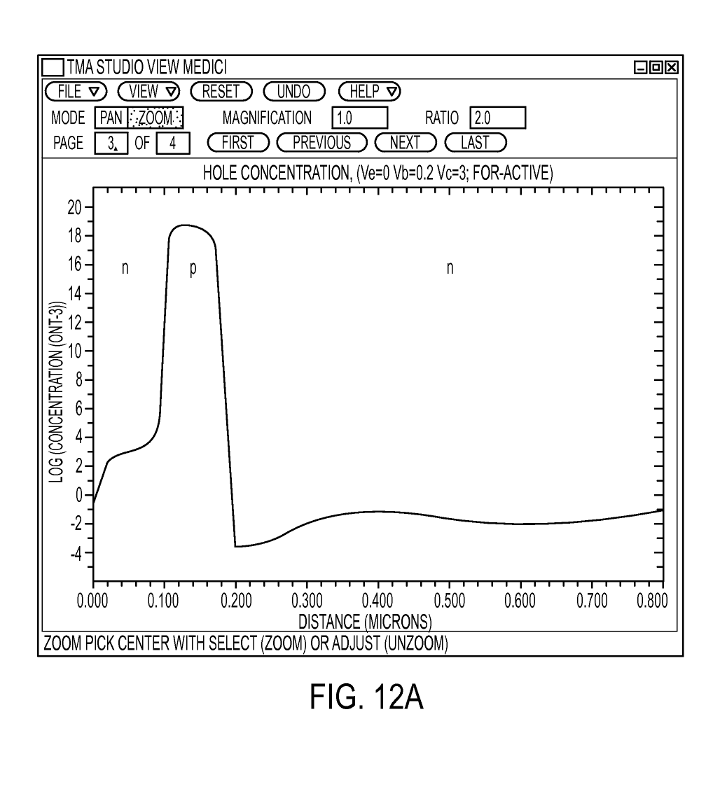

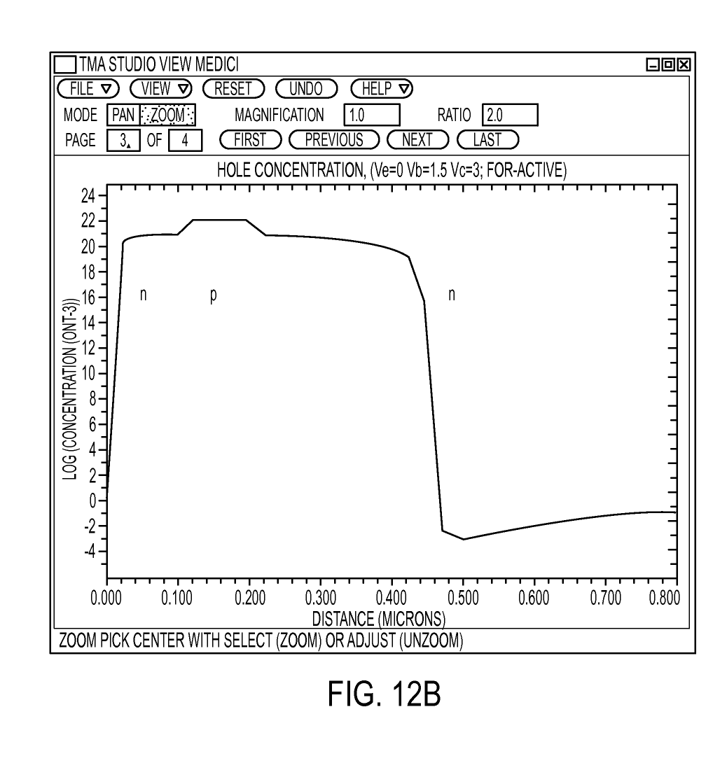

FIG. 12 shows the hole profile (which is the strongest contributor to the Drude Effect). The left profile is with a base emitter voltage of 0.2V while the right profile is for 1.5V. The device is in full base push-out on the right, with a thickness of the pushout around 4000 Angstroms, an order of magnitude more than the Debye length. In addition the hole carrier density is up around to. Because the thickness exclusive of base pushout is at least 3× that of the INTEL device, and the hole density is at least 1000× that of the INTEL device the length of the INTEL device can be enormously reduced especially in base pushout even without the photonic crystal enhancement. However, operating even in mild base pushout has undesirable speed consequences and the device slows down enormously from its native IT. Hence there are tradeoffs here between device speed, device size and power. Other modifications of the optical structure to shorten the device include the use of the photonic crystal slow wave structures discussed above, which reuse the carrier plasma repeatedly as the light passes under the HBT. A good working size is 100-200× shorter than the INTEL device and about 10× shorter than the Soref case, e.g. 10 microns for full π shift. This length is incredibly short compared to all the alternatives, so even if the device had some loss the other waveguide losses would be minimal.

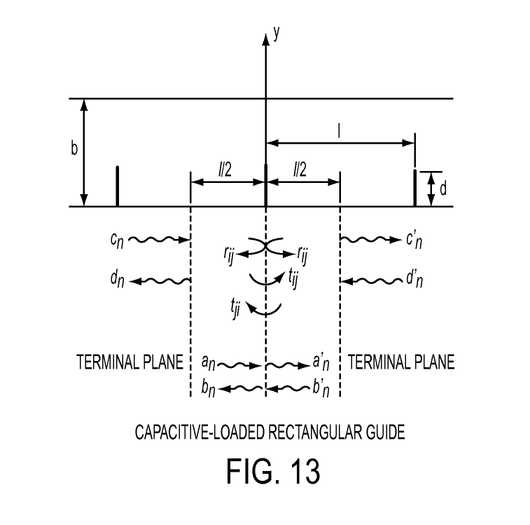

We have mentioned the inherent efficiency of reusing the carrier plasma under the HBT. It requires a certain amount of current to inject the holes and electrons in the emitter, base and collector. But once the carriers are there light can pass more than once through the plasma and slow down by the same amount each time. This can be accomplished by reflecting the light through different pathways in the plasma, back into it at different angles. But the most impressive reuse is to build a low Q resonator, in one example by employing a slow wave photonic crystal. Such a photonic crystal is shown in FIG. 13. We have discussed this earlier. The slow wave structure is as old as microwave waveguides. Collin shows a waveguide loaded with a periodic stud array. Electromagnetic waves enter from one side and encounter backward and forward scattering at each loading discontinuity. This is best shown in FIG. 14.

An additional consideration is that the light passing through the graded base SiGe HBT must be confined from the bottom. This typically will require perhaps an oxide, diamond or other dielectric layer which keeps reflecting the light back up under the free carrier plasma. If this is not done the light will eventually leak out from under the SiGe HBT into the Si substrate. For SiGe HBT devices implemented on a (possibly thick) Silicon on Oxide or SOI substrate the oxide of that wafer can provide this underlayer light confinement. This confinement from the bottom is not unlike the use of oxide walls on the optical waveguides used to route the light up to and away from the The graded base SiGe HBT 100 can be fabricated via the standard process described in Saitoh et al. No special Multiple Quantum Well or Stark Effect devices are needed that would require nonstandard processing at the device level. Even the INTEL FET capacitor is a somewhat non-standard device requiring process steps not in the standard line. So the SiGe HBT offers more straightforward way to incorporate HBT CML or CMOS circuitry into hybrid photonic/electronic systems. However, the Saitoh et al. process is an electronics wafer, and does not incorporate the new functionality of the invention to make this a photonics substrate. Consequently the optical guiding structure needs to be provided to get the light under the HBT. 3D processing techniques can thin the backside of the SiGe wafer exposing the underside of the HBT. By bonding this wafer onto a SOI wafer one has a chance to combine a wafer, which is more typically used for photonic wave guiding in Si. Other optical structures such as waveguides, photonic crystals, resonators, and polarizers which are not in the Saitoh et al. process can be fabricated on this second wafer, and by using 3D wafer to wafer bonding steps these two substrates can be joined, as shown in FIG. 15. However, further efforts can address improving alignment accuracy, or designing structures that can tolerate some misalignment.

To implement the underlayer beam confinement layer, in the case that this is not obtained using an SOI substrate, this underlayer needs to be implemented using further wafer thinning and stacking processes, which may involve 3D wafer bonding processes. As a method for realizing an embodiement, and for completeness, one such process will be discussed here. The first wafer bonding process is to a handling wafer, which then permits thinning the back side of the SiGe wafer to only a few microns to expose the HBT collector underside.

Since electrical conductivity below this is expected for the HBT and CMOS in the Saitoh et al. process any photonic substrate must provide this pathway. The second wafer bonding process would place the photonic substrate with its waveguides, gratings, photonic crystals, etc onto the exposed underside of the SiGe wafer, and the handling wafer is totally removed, leaving the upside down SiGe HBT's on the top of the photonic substrate. The photonic substrate can be either built into the back of that thinned substrate or bonded face to face with a separate photonic substrate (or a combination of these). Having a second substrate permits incorporation of a number of devices that might require very different fabrication steps, some at high temperature, which would be incompatible with the SiGe device wafer. Such integration is called 3D Heterogeneous Integration or HI. The minimal expectation is that the second substrate would be an SOI wafer with low loss waveguides, photonic crystal structures, Ge detectors, grating or rib structures, closely spaced directional coupler structures, ring resonators, and vertical couplers. The available equipment natively will produce 1 um alignment in x and y directions across the entire 8 inch wafer, but this can be enhanced by use of vertical surface asperities to help “nudge” or slide the wafers mechanically into closer alignment. This could be brought to 0.25 micron alignment in x or y, and wave crossing between the bonded wafers can be designed to be tolerant of this small alignment error.

The reason for the 3D approach is that the waveguide structure and associated photonic crystal must be positioned below the emitter, base and collector of the HBT, with protrusion of portions of the optical mode into the base and emitter. We have already shown that the photonic crystal can be used as a slow wave structure to reuse carrier plasma through repeated backward and forward reflections within the structure. However, the same photonic crystal can mode shape the propagating wave coupling into the HBT emitter base and collector region through the wafer bonding gap (which must be tuned) and up into the carrier plasma by evanescent extension through the plasma. The design of such a structure requires extensive calculations. The problem of course is that the standard BiCMOS process with 8 or 9 levels of metal wires, has no BEOL room for optical interconnections or vias in the interconnect stack, and the best (i.e. lowest attenuation) material for waveguides is a Si crystal substrate in any case. Unfortunately the very advantage of the SiGe high yield commercial process is also the disadvantage, nobody will want to alter the process for optical interconnections, so these must be added using 3D wafer bonding approaches. At least with this approach the photonic wafer can be passive with simple geometric structures.

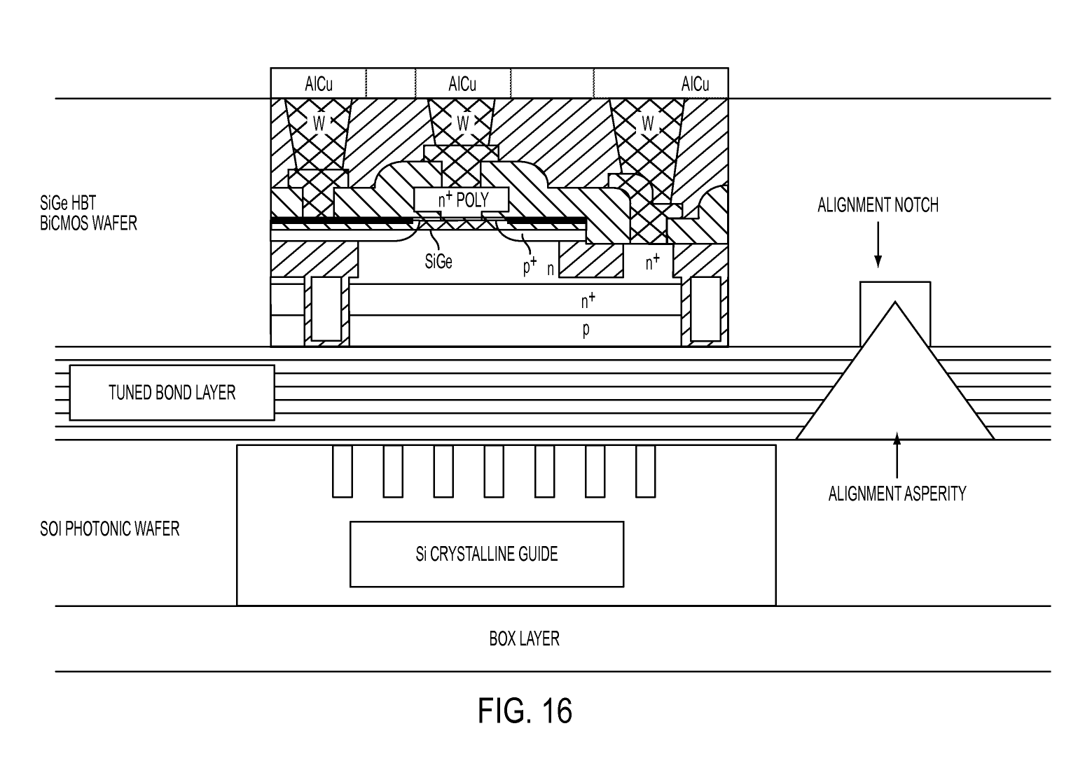

The challenges of this approach include the alignment accuracy of the two wafers, and the thickness, optical index, and uniformity of the bonding layer or approach. Typical face-to-face aligner accuracies today are only about 1 micron. However an approach to be developed in this work is the use of surface asperities to enhance that alignment accuracy. The thickness of the bonding layer is also a concern since it must couple well between the Si waveguide on the photonic wafer and the under-layer below the SiGe HBT (which is also on Si obviously). One can attempt to make the bonding layer extremely thin (much less than a wavelength of light for example) in order to minimize this effect, or deposit multilayer adhesives designed to tune for transmission between two Si layers. The presence of this layer between the waveguide on the photonic substrate must be modeled and incorporated into the photonic crystal design. Establishment of this intimate bond is extremely demanding given the wafer TTV, flexure and deformability of Si and bonding agents. In addition, while the photonic wave-guiding substrate can be fabricated on 8-inch SOI wafers where the BOX layer forms a natural etch stop layer in wafer-thinning, the HBT wafer is not implemented on an SOI wafer, and alternative methods for stopping the thinning process (such as hard Tungsten studs inserted from the top of the wafer) must be implemented and evaluated on blank wafers first. An example of this layered structure is shown schematically in FIG. 16.

One can see that there are a number of issues here, including alignment strategy, design of the Photonic Crystal, and coupling structure, guiding structure, coupling into the collector, base and emitter, and exquisite control over wafer thinning. However, it is clear that the main challenge of the 3D wafer bonding approach is the unknown loss and coupling efficiency associated with coupling light across the bonding layer between these two wafers and back into the photonic substrate waveguides to the next HBT involved in switching. One of the key technologies needed is precision wafer thinning. Unfortunately, with the SAITOH ET AL. SiGe HBT BiCMOS process the wafers are not SOI wafers and have no precision etch stopping layer. Yet the SiGe wafer must stop etching at or just below the sub-collector layer. Several approaches have been developed for etch stopping in this case, including an approach by Tezzaron to use W based plugs to act as hard stops on a CMP polishing wheel. These W plugs have to be inserted into the wafer to be thinned, and most importantly space in the chip layout to insert these must be provided ahead of time. The idea works with many non-SOI processes such as DRAM. However, the density of W studs is high, and this approach may not be precise enough to obtain 1-2 μm residual thicknesses with 1 to 10% thickness control on the final thickness.

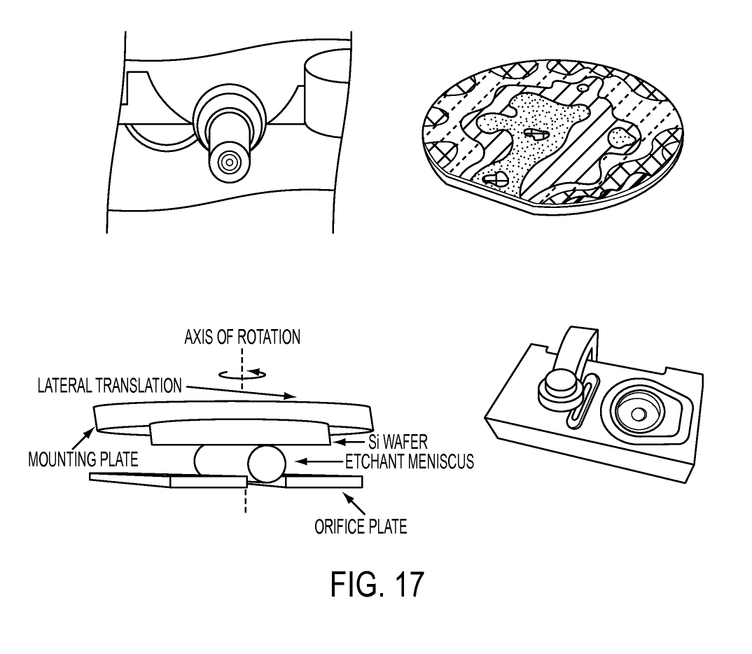

An interesting alternative is to measure the thickness of a partially thinned wafer (say at 50 um) using equipment made by Sematech and use the mathematics of computerized tomography to vary the dwell time of etching along a linear orifice through which an etchant meniscus just touches the wafer, proceeding along lateral sweeps across the wafer at different angles. The superposition of etch dwell times from different sweeps at all sweep angles across the same wafer surface can be arranged to just etch off the precisely computed excess. FIG. 17 shows precision wafer thinning by tomographic control using Sigma Tech Profiling and a MATECH linear sweep meniscus etchant system.

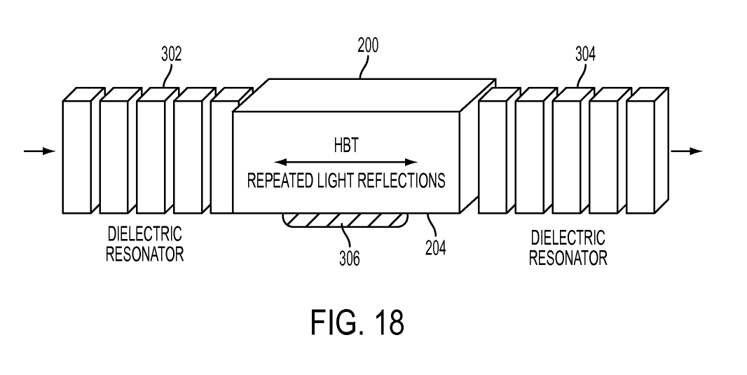

FIG. 18 shows another embodiment of the invention with the SiGe graded base EO modulator 200 positioned between a pair of dielectric resonators 302 and 304 in a Fabrey Perot configuration. Light enters the resonatator from the left and is partially reflected back and forth through the free carrier plasma effectively resusing the same carriers, permitting additional phase shift from each pass. For a low Q structure one might expect a length reduction of the device by OX while still permitting the ultra high speed of the graded base SiGe HBT to modulate the light rapidly. By shortening the device by plasma reuse the current required to inject the net charge is reduced, and hence the power associated with injection and ejection of the charge from the device is lowered. The low Q resonator imposes little bandwidth reduction on the modulation frequency, permitting some reduction in length and power whilst still preserving the ultimate speed for which the graded base SiGe HBT is capable. For example with a A of only 10-30 the device length might be reduced to only 10-20 microns, and the power per bit of binary communication to less than 1000 per bit.

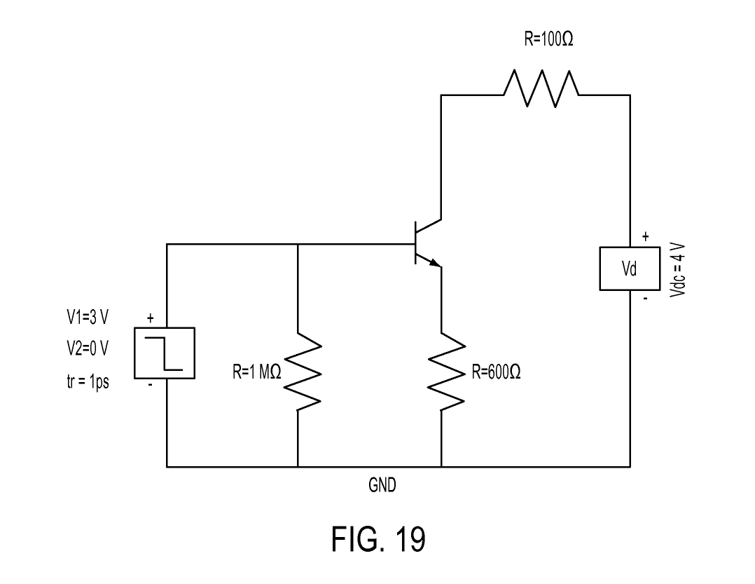

This type of structure is called a Fabry Perot resonator. This type of resonator typically has a low Q or quality factor meaning that the bandwidth of the optical resonator is not excessively narrow, and does not degrade the bandwidth of the optical modulation signal. The Low Q resonator enhances the performance of the SiGe HBT phase shifter by passing the light back and forth many times through the free carrier plasma. This permits a reuse of the same plasma, thereby enabling the reduction of the length of the device (with all the simplifications this implies) and a reduction in the total current needed to supply the free carrier charge, which reduces the average power and “energy per bit” in a digital modulation system. An optional photonic crystal 306 is positioned at a lower surface 204. FIG. 19 is a circuit schematic diagram of the SiGe graded base EO modulator 200. Resistors 206 and 208 are the biasing means. As shown in the figure the graded base SiGe HBT used to modulate the light must appear in an electrical circuit with biasing resistors and power supplies in order to inject and extract the free carrier plasma. In addition the base of the graded base SiGe HBT will require a driving signal which times these injections and extractions.

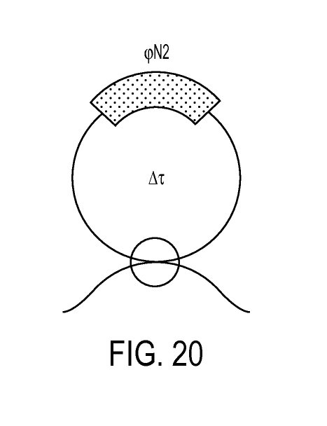

FIG. 20 shows a modification of the idea of the low-Q resonator, using instead a high Q optical ring resonator. The use of a high-Q resonator resonator such as a ring with a free carrier plasma phase shifter (shown in the figure as a dotted are representing a slightly curved graded base, SiGe HBT). Light traveling in the ring can make many passes through the free carrier plasma induced by the graded base SiGe HBT. The net phase shift can then detune the ring's resonant frequency, causing amplitude attenuation as the resonant frequency moves towards or away from the light's wavelength. While the ring may have a Q as high as 1.000 or more there may be ranges of modulator speeds where the bandwidth limitation of such a high Q resonator may still leave sufficient bandwidth to not limit the speed of the free carrier injection and ejection speed of the graded base SiGe HBT. The higher Q can then be used to lower length and power further.

The SiGe HBT EO modulator of the invention in one embodiment has an operation bandwidth of from about 2.4 GHz to about 10.4 GHz with a short L_{π} of 73.6 μm. The graded base NPN SiGe HBT that is based on Saitoh et al. as discussed below includes 8HP technology for fast EO modulation, and exhibits a [simulated] data transmission rate of 80 Gbits/s of the EO modulator for very short-haul backplane, interchip and intra-chip, board/package-level optical interconnections.

The free carrier effect is employed to shift the phase of light adequately to employ this mechanism in Mach Zehnder interferometers. Much faster speeds are possible using a SiGe HBT to inject and extract the free carrier plasma. Because only computational evidence is presented, at least two independent Computer Aided Design tools have been employed at each step of the simulation to cross check the results wherever possible. These tools strongly support the conclusion that modulation can be extended to 80 Gbits/s and perhaps to even higher speeds. An IBM certified CADENCE 8HP kit is used to validate the speed performance of the SiGe NPN HBT transistor. A two-dimensional MEDICI structure for the third generation SiGe HBT 8HP transistor is carefully constructed to study the necessary carrier dynamics. Comparison of these numerical simulations with those performed using MEDICI to extract the static, dynamic and transient characteristics of the device at small and large signal inputs confirms the accuracy of the model and the superior performance of SiGe 8HP compared to other Si based devices. The change in electron and hole carrier concentration is plotted from MEDICI for different base-emitter biases. The total charge obtained then is fed into the optical waveguide simulation software RSoft BeamProp, where an exactly similar structure compared to the MEDICI structure is created for mode calculation and extraction of L_{π}. The modal profiles of the device at various biases are also analyzed. For further confirmation this has been duplicated using finite-difference-time-domain (FDTD). The L_{π} for TM polarization is 240.8 μm at 1.1V base-emitter junction bias. A figure of merit is obtained of 0.0264 V-cm, which is the best combination obtained of the speed and device length without enhancement through the use of low Q resonant structures.

The HBT of the invention derives its electrical switching speed primarily from the thickness of its base region which is in the 0.04-0.1 micron range but the width of the emitter strength can be much wider than the channel length of a FET. Essentially the full capability of the HBT is retained up to very high switching frequencies, whereas the FET is severely limited in width and its ability to accommodate the optical wavelength at all. So the speed of the Graded Base SiGe HBT is its main advantage.

Thus, while the present invention has been described with respect to exemplary embodiments thereof, it will be understood by those of ordinary skill in the art that variations and modifications can be effected within the scope and spirit of the invention.

What is claimed as new and desired to be protected by Letters Patent of the United States is:

1. A graded base silicon-germanium (SiGe) heterojunction bipolar transistor (HBT)-based electro-optical (EU) modulator, comprising:
a graded base HBT; and
a light beam directed under the graded base HBT and passing through the free carrier plasma within for the purpose of inducing a phase modulation of the light beam.

2. The EU modulator of claim 1, further comprising a biasing means,

3. The EU modulator of claim 2, wherein the biasing means is one or more resistors, and possibly augmented with peaking inductors.

4. The modulator of claim 1, wherein the graded base HBT has a SiGe base composition graded such that a Si:Ge ratio by weight (mole fraction) is in the range of about 2% at the base-emitter junction portion of the SiGe base to about 7% or more (perhaps 20%) at an base-collector interface upper surface portion of the base.

5. In a graded base silicon-germanium (SiGe) heterojunction bipolar transistor (HBT) comprising:
a substrate;
an intrinsic base region having a silicon buffer layer comprising silicon formed on said substrate, and a composition-ratio graded base layer formed on the silicon buffer layer comprising silicon and germanium and where a composition ratio of the germanium to the silicon varies in a thickness direction of the composition-ratio graded base layer; and
an extrinsic base region having an extrinsic base formation layer comprising silicon formed on said substrate adjacent to the silicon buffer layer;
the improvement comprising a light source positioned inside the HBT for imparting an electro-optical modulator functionality to the HBT.

6. The EO modulator of claim 5, further comprising a biasing means,

7. The EO modulator of claim 6, wherein the biasing means is a resistor.

8. A graded base silicon-germanium (SiGe) heterojunction bipolar transistor (HBT)-based electro-optical (EO) modulator, comprising:
a graded base HBT; and
a light source positioned inside the graded base HBT.

9. The EO modulator of claim 8, further comprising a biasing means,

10. The EO modulator of claim 9, wherein the biasing means is a resistor.

11. The modulator of claim 8, wherein the graded base HBT has a SiGe base composition graded such that a Si:Ge ratio by weight (mole fraction) is in the range of about 2% at a base-emitter portion of the SiGe base to about 7% or more at an base collector portion of the base, said grading of the alloy to enhance the speed of the device.

12. The modulator of claim 8, further comprising a first dielectric reflector positioned on a first end of the modulator and a second dielectric reflector positioned on a second end of the Modulator to enhance the interaction of the light with the free carrier plasma using such a low Q structure, by bouncing the light back and forth through the same plasma sufficient times while yet not greatly limiting the bandwidth of the device.

13. The modulator of claim 12, further comprising a photonic crystal positioned on a lower surface of the modulator, to enhance the interaction of the light with the free carrier plasma using such a low Q structure, by bouncing the light back and forth through the same plasma sufficient times while yet not greatly limiting the bandwidth of the device.
